(19) United States
(12) Patent Application Publication
(10) Pub. No.: US 2014/0050024 A1
(43) Pub. Date: Feb. 20, 2014

(54) DATA READING METHOD, AND CIRCUIT, REWRITABLE NON-VOLATILE MEMORY MODULE AND MEMORY STORAGE APPARATUS USING THE SAME

(71) Applicant: PHISON ELECTRONICS CORP., Miaoli (TW)

(72) Inventors: Riichiro Shirota, Hsinchu City (TW); Wei Lin, Taipei City (TW)

(73) Assignee: PHISON ELECTRONICS CORP., Miaoli (TW)

(21) Appl. No.: 13/781,718

(22) Filed: Feb. 28, 2013

Related U.S. Application Data
(60) Provisional application No. 61/683,680, filed on Aug. 15, 2012.

(30) Foreign Application Priority Data
Nov. 5, 2012 (TW) 101141021

(51) Int. Cl. G11C 16/26

(52) U.S. Cl. CPC G11C 16/26
USPC 365/185.03

(57) ABSTRACT

A data reading method for a rewritable non-volatile memory module, a memory controller using the method, and a memory storage apparatus using the method are provided. The method includes applying a bias for reading data to a target word line electrically connected to a target memory cell and applying a bias for selecting bit lines to a target bit line electrically connected to the target memory cell. The method also includes applying a first bias to at least one word line adjacent to the target word line and applying a second bias to other word lines, and the first bias is lower than the second bias. The method further includes outputting a corresponding value according to a conduction state of a channel of the target memory cell. Accordingly, the method can effectively increase the gate controllability of the memory cell to prevent read errors.

### CROSS-REFERENCE TO RELATED APPLICATION

This application claims the priority benefits of U.S. provisional application Ser. No. 61/683,680, filed on Aug. 15, 2012 and Taiwan application serial no. 101141021, filed on Nov. 5, 2012. The entirety of each of the above-mentioned patent applications is hereby incorporated by reference herein and made a part of this specification.

### BACKGROUND

1. Technology Field

The present invention relates to a data reading method, a circuit using the method, a rewritable non-volatile memory module using the same and a memory storage apparatus using the method.

2. Description of Related Art

Digital cameras, cell phones, and MP3 players have undergone rapid growth in recent years, so that consumers' demands for storage media have also increased drastically. Since a rewritable non-volatile memory has the characteristics of non-volatility of data, low power consumption, small volume, non-mechanical structure, and fast reading and writing speed, the rewritable non-volatile memory is the most adaptable memory to be applied in a portable electronic product, e.g., a notebook computer. A solid state drive (SSD) is a storage apparatus which utilizes a flash memory as its storage medium. Therefore, the flash memory industry has become a very popular part of the electronic industry in recent years.

In a NAND flash memory, memory cells are linked through bit lines and word lines to form a memory cell array. At present, the NAND flash memory may be classified into a multi-level cell (MLC) NAND flash memory and a single-level cell (SLC) NAND flash memory according to the number of bits which may be stored in each memory cell. Each memory cell can store one bit of data in the SLC NAND flash memory, and each memory cell can store at least two bits of data in the MLC NAND flash memory. For instance, in an exemplary 4-level cell NAND flash memory, each memory cell may store 2 bits of data (i.e., “11,” “10,” “00,” or “01”).

FIG. 1 is a schematic diagram illustrating a flash memory device according to the related art.

With reference to FIG. 1, a flash memory device 1 includes a charge-trapping layer 2 for storing electrons, a control gate 3 for applying a bias voltage, a tunnel oxide layer 4, and an interpoly dielectric layer 5. When it is intended to write data into the flash memory device 1, a threshold voltage of the flash memory device 1 may be changed by injecting electrons into the charge-trapping layer 2. Accordingly, a digital-level state of the flash memory device 1 is defined to implement a function of storing data. Here, the process of injecting the electrons to the charge-trapping layer 2 is referred to as a programming process. By contrast, when it is intended to remove the stored data, the injected electrons are removed from the charge-trapping layer 2, and thereby the flash memory device 1 is restored back to the default state before programming.

When a control circuit for controlling these bit and word lines applies a bias for reading data from an assigned memory cell, turn-on voltages applied to other memory cells may generate parasitic capacitance effects on the assigned memory cell. Thereby, the gate controllability of the assigned memory cell is reduced, and error bits may occur (i.e., data (also referred to as “read data”) read from a memory cell by the control circuit are different from data (also referred to as “write data”) originally written into the memory cell). Accordingly, people skilled in the art pay close attention to the way to prevent the read errors.

Nothing herein should be construed as an admission of knowledge in the prior art of any portion of the invention. Furthermore, citation or identification of any document in this application is not an admission that such document is available as prior art to the invention, or that any reference forms a part of the common general knowledge in the art.

### SUMMARY

Accordingly, the present invention is directed to a data reading method, a memory controller, and a memory storage apparatus capable of effectively preventing read errors.

In an exemplary embodiment of the present invention, a data reading method for a rewritable non-volatile memory module is provided. The rewritable non-volatile memory module has a plurality of memory cells, a plurality of word lines, and a plurality of bit lines, and each of the memory cells is electrically connected to one of the word lines and one of the bit lines. The data reading method includes applying a bias for reading data to a target word line and applying a bias for selecting bit lines to a target bit line. Here, the target word line is one of the word lines electrically connected to a target memory cell of the memory cells, and the target bit line is one of the bit lines electrically connected to the target memory cell. The data reading method also includes applying a first bias to at least one first word line of the word lines and applying a second bias to the other word lines. Here, the at least one first word line is adjacent to the target word line, and the first bias is lower than the second bias. The data reading method further includes outputting a corresponding value according to a conduction state of a channel of the target memory cell.

In an exemplary embodiment of the invention, a circuit for reading data is provided. The circuit includes an interface and a memory management circuit. The interface is configured to couple to a plurality of memory cells, a plurality of word lines, and a plurality of bit lines. The memory management circuit is coupled to the interface. The memory management circuit is configured to give an instruction to apply a bias for reading data to a target word line and apply a bias for selecting bit lines to a target bit line. Here, the target word line is one of the word lines electrically connected to a target memory cell of the memory cells, and the target bit line is one of the bit lines electrically connected to the target memory cell. The memory management circuit is further configured to give an instruction to apply a first bias to at least one first word line of the word lines and give an instruction to apply a second bias to the other word lines. Here, the at least one first word line is adjacent to the target word line, and the first bias is lower than the second bias. The memory management circuit is further configured to output a corresponding value according to a conduction state of a channel of the target memory cell.

In an exemplary embodiment of the invention, a memory storage apparatus that includes a connector, a rewritable non-volatile memory module, and a memory controller is provided. The connector is configured to couple to a host system. The rewritable non-volatile memory module has a plurality of memory cells, a plurality of word lines, and a plurality of bit lines, and each of the memory cells is electrically connected to one of the word lines and one of the bit lines. The memory controller is coupled to the connector and the rewritable non-volatile memory module. The memory controller is configured to give an instruction to apply a bias for reading data to a target word line and apply a bias for selecting bit lines to a target bit line. Here, the target word line is one of the word lines electrically connected to a target memory cell of the memory cells, and the target bit line is one of the bit lines electrically connected to the target memory cell. The memory controller is further configured to give an instruction to apply a first bias to at least one first word line of the word lines and give an instruction to apply a second bias to the other word lines. Here, the at least one first word line is adjacent to the target word line, and the first bias is lower than the second bias. The memory controller is further configured to output a corresponding value according to a conduction state of a channel of the target memory cell.

In an exemplary embodiment of the invention, a rewritable non-volatile memory module is provided. The rewritable non-volatile memory module includes has a plurality of memory cells, a plurality of word lines, and a plurality of bit lines, and a control circuit. The plurality of word lines electrically connect to at least one of the of the memory cells, the plurality of bit lines electrically connect to at least one of the of the memory cells, and the control circuit electrically connects to the plurality of memory cells, the plurality of word lines, and the plurality of bit lines. The control circuit is configured to apply a bias for reading data to a target word line, and the target word line is one of the word lines electrically connected to a target memory cell among the memory cells. The control circuit is further configured to apply a bias for selecting the bit lines to a target bit line, and the target bit line is one of the bit lines electrically connected to the target memory cell. The control circuit is further configured to give an instruction to apply a first bias to at least one first word line among the word lines, and the at least one first word line is adjacent to the target word line. The control circuit is further configured to give an instruction to apply a second bias to the other word lines. The control circuit is further configured to output a corresponding value according to a conduction state of a channel of the target memory cell, and the first bias is lower than the second bias.

In view of the above, the data reading method, the control circuit, the rewritable non-volatile memory module and the memory storage apparatus described in the exemplary embodiments of the present invention are capable of effectively minimizing the parasitic capacitance effects on the read memory cell and improving the gate controllability, and thereby data read error may be prevented.

It should be understood, however, that this Summary may not contain all of the aspects and embodiments of the invention, is not meant to be limiting or restrictive in any manner, and that the invention as disclosed herein is and will be understood by those of ordinary skill in the art to encompass obvious improvements and modifications thereto.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a flash memory device according to the related art.

FIG. 2 illustrates a host system and a memory storage apparatus according to an exemplary embodiment of the present invention.

FIG. 3 is a schematic diagram illustrating a computer, an input/output (I/O) device, and a memory storage apparatus according to an exemplary embodiment of the present invention.

FIG. 4 is a schematic diagram illustrating a host system and a memory storage apparatus according to an exemplary embodiment of the present invention.

FIG. 5 is a schematic block diagram illustrating a memory storage apparatus according to an exemplary embodiment of the present invention.

FIG. 6 is a schematic block diagram illustrating a rewritable non-volatile memory module according to an exemplary embodiment of the present invention.

FIG. 7 is a schematic diagram illustrating a memory cell array according to an exemplary embodiment of the present invention.

FIG. 8 is a statistical distribution diagram illustrating gate voltages corresponding to data stored in a memory array according to an exemplary embodiment of the present invention.

FIG. 9 is a schematic diagram of verifying a storage state of a memory cell according to an exemplary embodiment of the present invention.

FIG. 10 is a schematic diagram of verifying a storage state of a memory cell according to another exemplary embodiment of the present invention.

FIG. 11 is a schematic block diagram illustrating a memory controller according to an exemplary embodiment of the present invention.

FIG. 12 is schematic diagram of applying biases to a word line and a bit line for reading data from a memory cell according to an exemplary embodiment of the present invention.

FIG. 13 is a flowchart illustrating a data reading method according to an exemplary embodiment of the present invention.

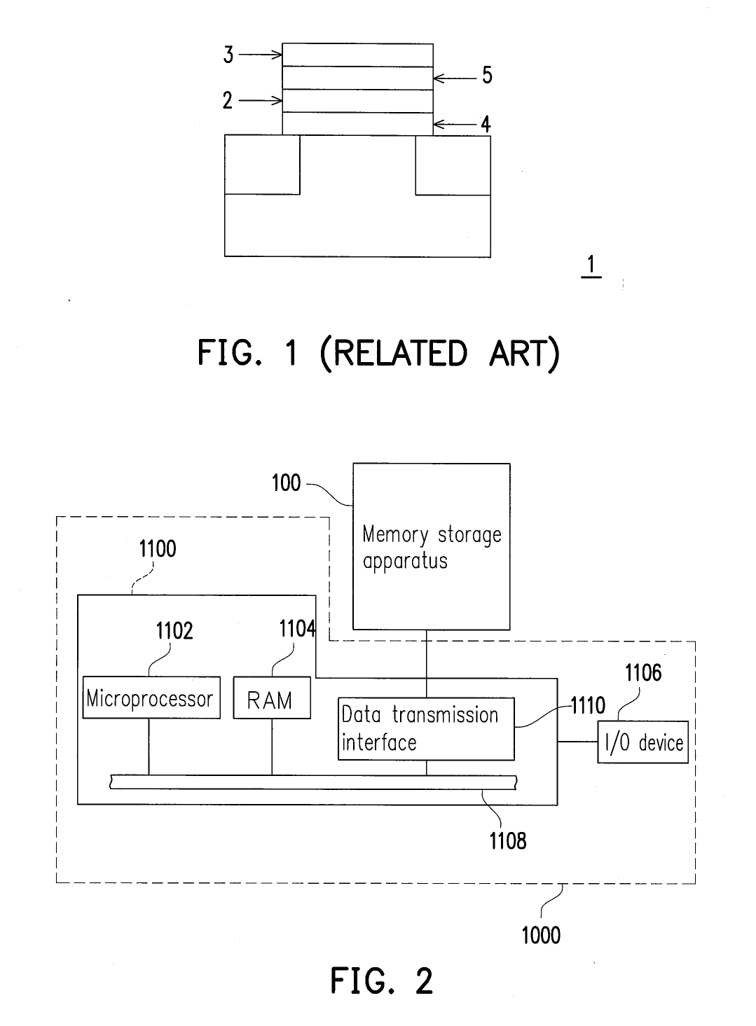

### DESCRIPTION OF EMBODIMENTS

Reference will now be made in detail to the present exemplary embodiments of the invention, examples of which are illustrated in the accompanying drawings. Wherever possible, the same reference numbers are used in the drawings and the description to refer to the same or like parts. Embodiments of the invention may comprise any one or more of the novel features described herein, including in the detailed description, and/or shown in the drawings. As used herein, “at least one,” “one or more,” and “and/or” are open-ended expressions that are both conjunctive and disjunctive in operation. For instance, each of the expressions “at least on of A, B and C,” “at least one of A, B, or C,” “one or more of A, B, and C,” “one or more of A, B, or C,” and “A, B, and/or C” means A alone, B alone, C alone, A and B together, A and C together, B and C together, or A, B and C together. It is to be noted that the term “a” or “an” entity refers to one or more of that entity. As such, the terms “a” (or “an”), “one or more,” and “at least one” can be used interchangeably herein.

A memory storage apparatus (also referred to as a memory storage system) typically includes a rewritable non-volatile memory module and a controller (also referred to as a control circuit). The memory storage apparatus is usually used together with a host system, such that the host system can write data into or read data from the memory storage apparatus.

FIG. 2 illustrates a host system and a memory storage apparatus according to an exemplary embodiment of the present invention.

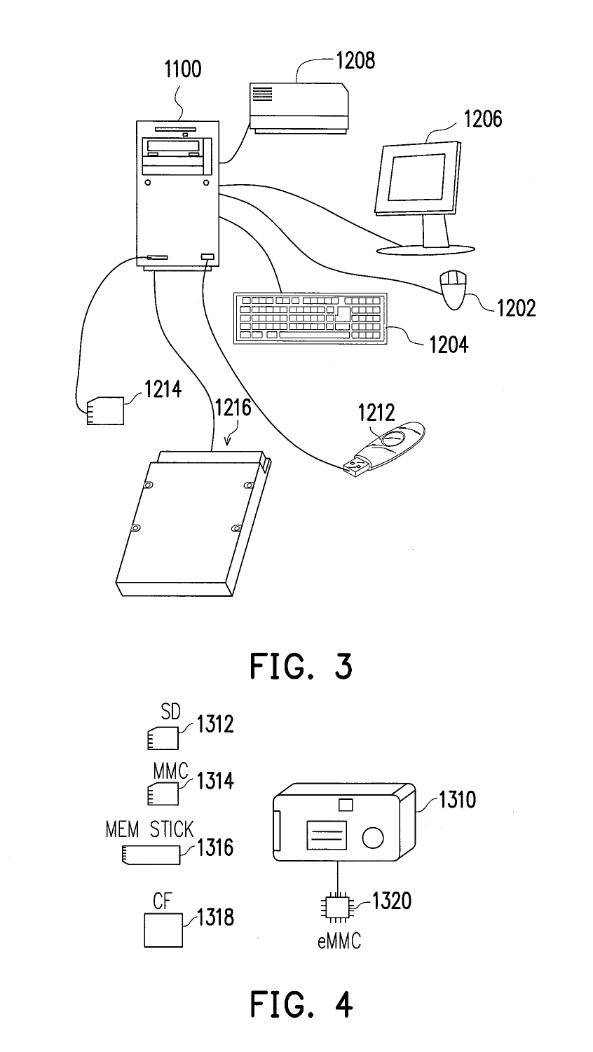

With reference to FIG. 2, a host system 1000 normally includes a computer 1100 and an input/output (I/O) device 1106. The computer 1100 includes a microprocessor 1102, a random access memory (RAM) 1104, a system bus 1108, and a data transmission interface 1110. The I/O device 1106 includes a mouse 1202, a keyboard 1204, a display 1206, and a printer 1252 as shown in FIG. 3. It should be understood that the I/O device 1106 is not limited to include the devices shown in FIG. 3 and may further include other devices.

In the exemplary embodiment of the present invention, the memory storage apparatus 100 is coupled to other devices of the host system 1000 through the data transmission interface 1110. By operating the microprocessor 1102, the RAM 1104, and the I/O device 1106, the data can be written into or read from the memory storage apparatus 100. For instance, the memory storage apparatus 100 may be a rewritable non-volatile memory storage apparatus, such as a flash drive 1256, a memory card 1214, or a solid state drive (SSD) 1216 shown in FIG. 3.

Generally, the host system 1000 can substantially be any system operated together with the memory storage apparatus 100 for storing data. Even though the host system 1000 is described as a computer system in the present exemplary embodiment, the host system 1000 in another exemplary embodiment may be a digital camera, a video camera, a communication device, an audio player, a video player, and so forth. For instance, if the host system is a digital camera (video camera) 1310, the rewritable non-volatile memory storage apparatus is then an SD card 1312, an MMC card 1314, a memory stick 1316, a CF card 1318, or an embedded storage device 1320 (as shown in FIG. 4). The embedded storage device 1320 includes an embedded MMC (eMMC). It should be mentioned that the eMMC is directly coupled to the substrate of the host system.

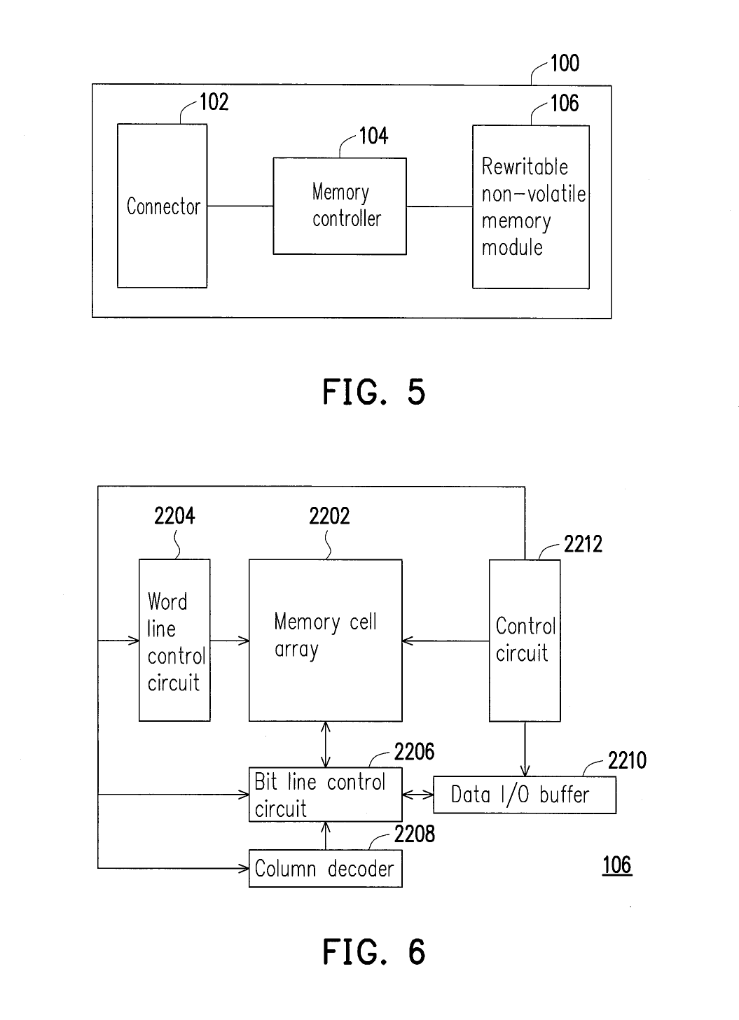

FIG. 5 is a schematic block diagram illustrating a memory storage apparatus according to an exemplary embodiment of the present invention.

With reference to FIG. 5, the memory storage apparatus 100 includes a connector 102, a memory controller 104, and a rewritable non-volatile memory module 106.

In the present exemplary embodiment, the connector 102 complies with a universal serial bus (USB) standard. However, it should be understood that the invention is not limited thereto, and the connector 102 may also comply with the parallel advanced technology attachment (PATA) standard, the Institute of Electrical and Electronic Engineers (IEEE) 1394 standard, the peripheral component interconnect (PCI) express standard, the secure digital (SD) standard, the serial advanced technology attachment (SATA) standard, the ultra high speed-I (UHS-I) interface standard, the ultra high speed-II (UHS-II) interface standard, the memory sick (MS) interface standard, the multi media card (MMC) interface standard, the eMMC interface standard, the universal flash storage (UFS) interface standard, the compact flash (CF) standard, the integrated device electronics (IDE) standard, or other suitable standards.

The memory controller 104 is configured to execute a plurality of logic gates or control instructions implemented in a hardware form or a firmware form and perform various data operations (e.g., data writing, reading, and erasing) in the rewritable non-volatile memory module 106 according to commands issued by the host system 1000.

The rewritable non-volatile memory module 106 is coupled to the memory controller 104 and configured to store data written by the host system 1000. In the present exemplary embodiment, the rewritable non-volatile memory module 106 is a multi-level cell (MLC) NAND flash memory module (i.e., a flash memory module capable of storing data of 2 bits in one memory cell). However, the invention is not limited thereto, and the rewritable non-volatile memory module 106 may also be a single-level cell (SLC) NAND flash memory module (i.e., a flash memory module capable of storing data of 1 bit in one memory cell), a trinary-level cell (TLC) NAND flash memory module (i.e., a flash memory module capable of storing data of 3 bits in one memory cell), other flash memory modules, or other memory modules having the same characteristics.

FIG. 6 is a schematic block diagram illustrating a rewritable non-volatile memory module according to an exemplary embodiment of the present invention.

With reference to FIG. 6, the rewritable non-volatile memory module 106 includes a memory cell array 2202, a word line control circuit 2204, a bit line control circuit 2206, a column decoder 2208, a data input/output (I/O) buffer 2210, and a control circuit 2212.

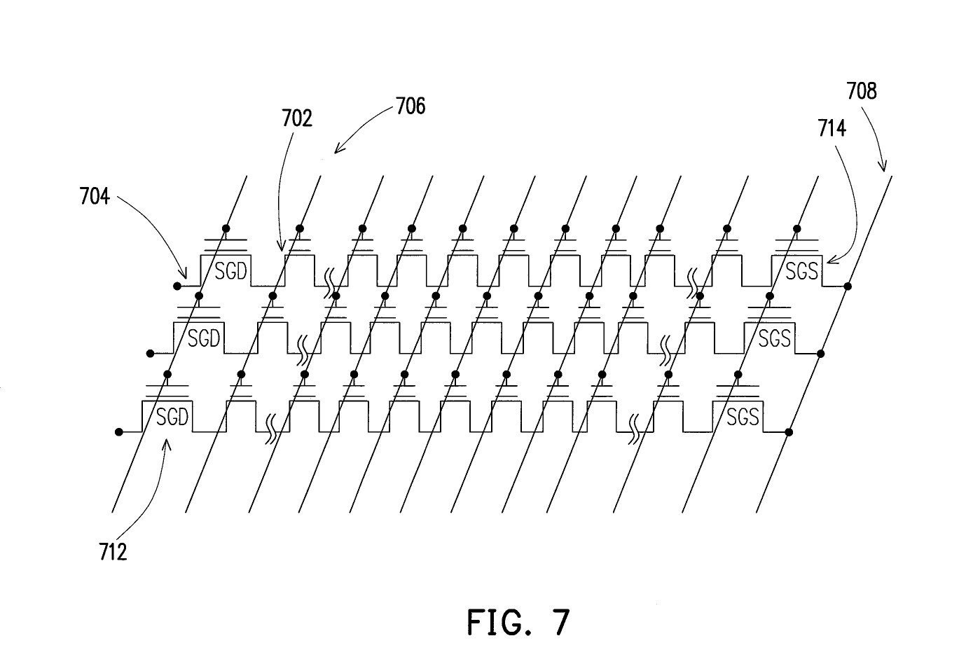

The memory cell array 2202 includes a plurality of memory cells 702 for storing data, a plurality of select gate drain (SGD) transistors 712, a plurality of select gate source (SGS) transistors 714, a plurality of bit lines 704 for connecting the memory cells, a plurality of word lines 706, and a common source line 708 (as shown in FIG. 7). The memory cells 702 are disposed on the cross points of the bit lines 704 and the word lines 706 as an array. When a write command or a read command is received from the memory controller 130, the control circuit 2212 controls the word line control circuit 2204, the bit line control circuit 2206, the column decoder 2208, and the data I/O buffer 2210 to write data into the memory cell array 202 or read data from the memory cell array 202, wherein the word line control circuit 2204 is configured to control the bias applied to the word lines 706, the bit line control circuit 2206 is configured to control the bias applied to the bit lines 704, the column decoder 2208 selects the corresponding bit line according to the decoding column address in the command, and the data I/O buffer 2210 is configured to store the data temporarily.

In the present exemplary embodiment, the rewritable non-volatile memory module 106 is an MLC NAND flash memory module which employs a plurality of gate voltages for representing a multi-bit data. To be specific, each memory cell of the memory cell array 2202 has a plurality of storage states, and the storage states are distinguished by a plurality of threshold voltages.

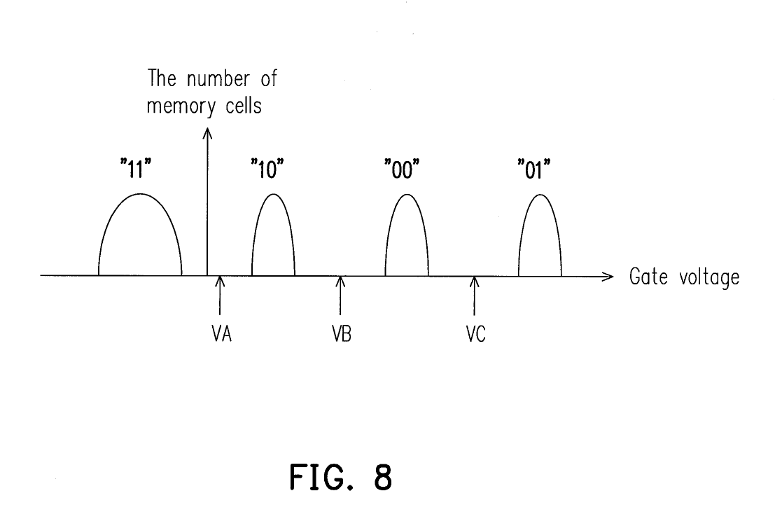

FIG. 8 is a statistical distribution diagram illustrating gate voltages corresponding to data stored in a memory array according to an exemplary embodiment of the present invention.

With reference to FIG. 8, in an exemplary MLC NAND flash memory, the gate voltage in each memory cell may be categorized into 4 storage states according to a first threshold bias VA, a second threshold bias VB, and a third threshold bias VC, and these storage states respectively represent “11,” “10,” “00,” and “01.” In other words, each storage state includes the least significant bit (LSB) and the most significant bit (MSB). In the present exemplary embodiment, the first bit from the left of the storage states (i.e., “11,” “10,” “00,” and “01”) is the LSB, and the second bit from the left of the storage states is the MSB. Therefore, in the exemplary embodiment, each memory cell stores 2 bits of data. It should be understood that the gate voltages and the corresponding storage states illustrated in FIG. 8 are only examples. In another exemplary embodiment of the present invention, the gate voltages and the corresponding storage states may also have such an arrangement as “11,” “10,” “01,” and “00” along with the increase in the gate voltages. Alternatively, the storage states corresponding to the gate voltages may also be values obtained by mapping or inverting actual storage values. Besides, in yet anther exemplary embodiment, the first bit from the left may be defined as the MSB, and the second bit from the left may be defined as the LSB. In the present exemplary embodiment, each memory cell stores 2 bits of data of 2 bits; hence, the memory cells on the same word line constitute a storage space of 2 physical pages (i.e., a lower page and an upper page). Namely, the LSB of each memory cell corresponds to the lower page, and the MSB of each memory cell corresponds to the upper page. In addition, several physical pages in the memory cell array 2202 constitute a physical block, and the physical block is the smallest unit for erasing data. Namely, each physical block contains the least number of memory cells which are erased all together.

To write (or to program) data to a memory cell of the memory cell array 2202, a voltage (e.g., a gate voltage) applied to a certain terminal in the memory cell is controlled to change the electron volume in a charge-trapping layer in the gate, so that the conduction state of the channel of the memory cell is changed to present a different storage state. For instance, when the lower page data is 1, and the upper page data is 1 as well, the control circuit 2212 controls the word line control circuit 2204 not to change the gate voltage in the memory cell, so as to keep the storage state of the memory cell as “11.” When the lower page data is 1, and the upper page data is 0, the control circuit 2212 controls the word line control circuit 2204 to change the gate voltage in the memory cell, so as to change the storage state of the memory cell to “10.” When the lower page data is 0, and the upper page data is 0 as well, the control circuit 2212 controls the word line control circuit 2204 to change the gate voltage in the memory cell, so as to change the storage state of the memory cell to “00.” When the lower page data is 0, and the upper page data is 1, the control circuit 2212 controls the word line control circuit 2204 to change the gate voltage in the memory cell, so as to change the storage state of the memory cell to “01.”

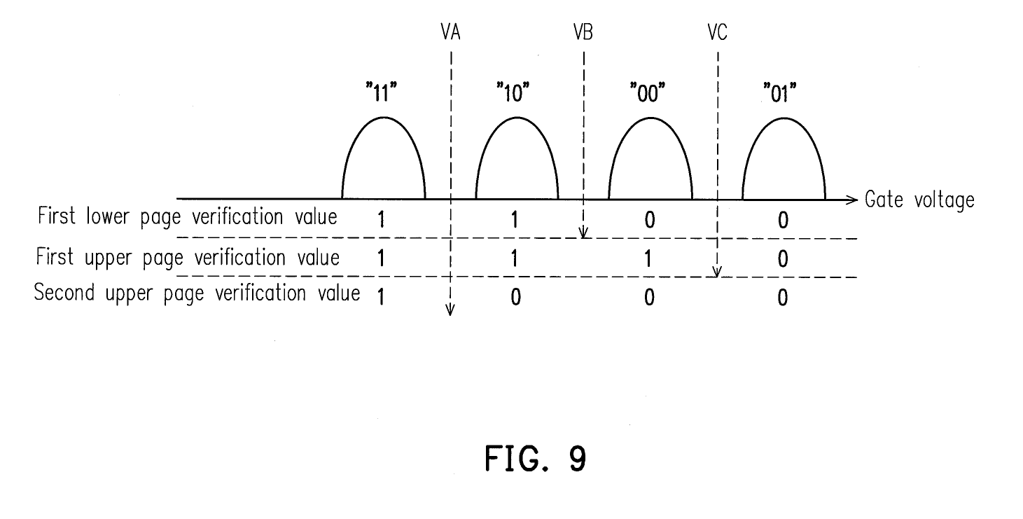

FIG. 9 is a schematic diagram of verifying a storage state of a memory cell according to an exemplary embodiment of the present invention.

With reference to FIG. 9, in order to read data from a memory cell of the memory cell array 2202, a bias for reading data is applied to a control gate; by means of the conduction state of a channel of the memory cell, the data stored in the memory cell may be indicated. Here, the channel of the memory cell refers to an electrical connection path between the bit lines and the source lines of the memory cell (e.g., the path between the source and the drain of the memory cell). In an operation for reading data from a lower page, the word line control circuit 2204 applies the second threshold bias VB (as the bias for reading data) to the memory cell and determines the value of the lower page data according to whether the channel of the memory cell is conducted and the corresponding expression (1):

LSB=(VB)Lower_pre1 (1)

In the expression (1), (VB)Lower_pre1 represents a first lower page verification value obtained by applying the second threshold bias VB.

For instance, when the second threshold bias VB is lower than the gate voltage in the memory cell, the channel of the memory cell is not conducted, and a first lower page verification value, which is ‘0’, is output. Accordingly, the LSB is indicated to be in a first state as 0. When the second threshold bias VB is higher than the gate voltage in the memory cell, the channel of the memory cell is conducted, and the first lower page verification value, which is ‘1’, is output. Accordingly, the LSB is indicated as being in a second state. Here, the first state is indicated as “0,” and the second state is indicated as “1.” That is, the gate voltage for presenting the LSB as “1” and the gate voltage for presenting the LSB as “0” may be distinguished by the second threshold bias VB.

In an operation for reading data from an upper page, the word line control circuit 2204 respectively applies the third threshold bias VC and the first threshold bias VA (collectively as the bias for reading data) to the memory cell and determines the value of the upper page data according to whether the channel of the memory cell is conducted and the corresponding expression (2):

MSB=((VA)Upper_pre2)xor(˜(VC)Upper_{—pre}1) (2)

In the expression (2), (VC)Upper_pre1 represents a first upper page verification value obtained by applying the third threshold bias VC, and (VA)Upper_pre2 represents a second upper page verification value obtained by applying the first threshold bias VA, wherein the symbol “˜” represents inversion. Additionally, in the present exemplary embodiment, when the third threshold bias VC is lower than the gate voltage in the memory cell, the channel of the memory cell is not conducted, and the first upper page verification value ((VC)Upper_pre1), which is ‘0’, is output; when the first threshold bias VA is lower than the gate voltage in the memory cell, the channel of the memory cell is not conducted, and a second upper page verification value ((VA)Upper_pre2), which is ‘0’, is output.

Thus, in the present exemplary embodiment, according to the expression (2), it is assumed that the third threshold bias VC and the first threshold bias VA are both lower than the gate voltage in the memory cell. When the third threshold bias VC is applied, the channel of the memory cell is not conducted, and a first upper page verification value, which is ‘0’, is output; when the first threshold bias VA is applied, the channel of the memory cell is not conducted, and a second upper page verification value, which is ‘0’, is output.

At this time, the MSB is indicated as being in the second state, i.e., “1.”

For instance, it is assumed that the third threshold bias VC is higher than the gate voltage of the memory cell, and the first threshold bias VA is lower than the gate voltage of the memory cell. When the third threshold bias VC is applied, the channel of the memory cell is conducted, and a first upper page verification value, which is ‘b 1’, is output; when the first threshold bias VA is applied, the channel of the memory cell is not conducted, and a second upper page verification value, which is ‘0’, is output. At this time, the MSB is indicated, as being in the first state, i.e., “0.”

For instance, it is assumed that the third threshold bias VC and the first threshold bias VA are both higher than the gate voltage of the memory cell. When the third threshold bias VC is applied, the channel of the memory cell is conducted, and a first upper page verification value, which is ‘1’, is output; when the first threshold bias VA is applied, the channel of the memory cell is conducted, and a second upper page verification value, which is ‘1’, is output.

At this time, the MSB is indicated as being in the second state, i.e., “1.”

It should be understood that the exemplary MLC NAND flash memory described herein should not be construed as limitation to the invention, and data can be read from any other MLC NAND flash memory through the principle described above.

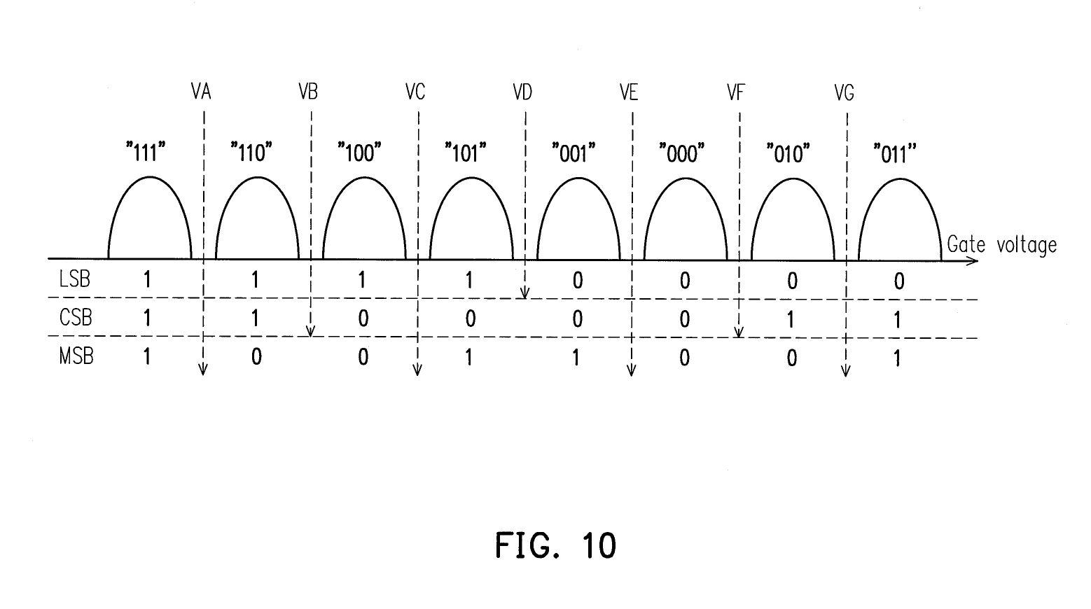

For instance, in an exemplary TLC NAND flash memory (as shown in FIG. 10), each storage state includes an LSB (the first bit from the left), a center significant bit (CSB, the second bit from the left), and an MSB (the third bit from the left), wherein the LSB corresponds to a lower page, the CSB corresponds to a center page, and the MSB corresponds to an upper page. In this example, the gate voltage in each memory cell is distinguished into 8 storage states (i.e., “111,” “110,” “100,” “101,” “001,” “000,” “010,” and “011”) according to a first threshold bias VA, a second threshold bias VB, a third threshold bias VC, a fourth threshold bias VD, a fifth threshold bias VE, a sixth threshold bias VF, and a seventh threshold bias VG. Moreover, in an exemplary SLC NAND flash memory (not shown), only 1 bit of data is stored in a storage state, and thus the gate voltage in each memory cell indicates the storage states (i.e., “1” and “0”) of the memory cell according to a threshold bias.

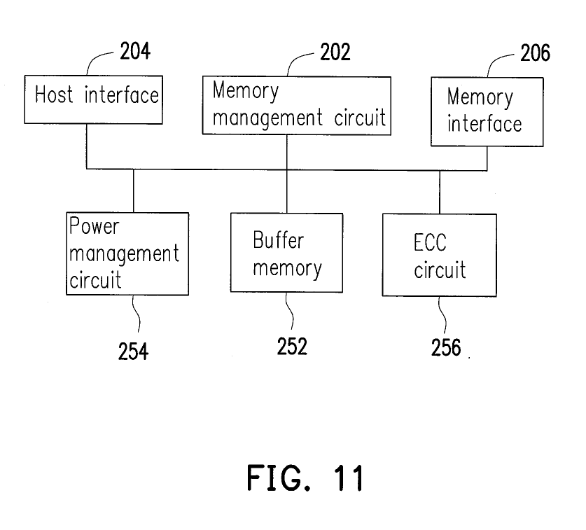

FIG. 11 is a schematic block diagram illustrating a memory controller according to an exemplary embodiment of the present invention. It should be understood that the structure of the memory controller depicted in FIG. 11 is merely exemplary and should not be construed as a limitation to the invention.

With reference to FIG. 11, the memory controller 104 includes a memory management circuit 202, a host interface 204, and a memory interface 206.

The memory management circuit 202 is configured to control the overall operation of the memory controller 104. Particularly, the memory management circuit 202 has a plurality of control instructions; when the memory storage apparatus 100 is operated, the control instructions are executed to perform a data writing operation, a data reading operation, a data erasing operation, and so on.

In the present exemplary embodiment, the control instructions of the memory management circuit 202 are implemented in a firmware form. For instance, the memory management circuit 202 has a microprocessor unit (not shown) and a read-only memory (ROM, not shown), and these control instructions are burnt into the ROM. When the memory storage apparatus 100 is in operation, the control instructions are executed by the microprocessor unit to write, read, and erase data.

In another exemplary embodiment of the invention, the control instructions of the memory management circuit 202 may also be stored in a specific area of the rewritable non-volatile memory module 106 (e.g., a system area of a memory module exclusively used for storing system data) in form of program codes. Additionally, the memory management circuit 202 may have a microprocessor unit (not shown), a ROM (not shown), and a RAM (not shown). In particular, the ROM has boot codes, and when the memory controller 104 is enabled, the microprocessor unit first executes the boot codes to load the control instructions from the rewritable non-volatile memory module 106 into the RAM of the memory management circuit 202. The microprocessor unit then executes the control instructions to write, read, and erase data.

Moreover, the control instructions of the memory management circuit 202 may also be implemented in a hardware form according to another exemplary embodiment of the invention. For instance, the memory management circuit 202 includes a microcontroller, a memory cell management circuit, a memory writing circuit, a memory reading circuit, a memory erasing circuit, and a data processing circuit. The memory cell management circuit, the memory writing circuit, the memory reading circuit, the memory erasing circuit, and the data processing circuit are coupled to the microcontroller. The memory cell management circuit is configured to manage physical erasing units of the rewritable non-volatile memory module 106. The memory writing circuit is configured to issue a write command to the rewritable non-volatile memory module 106 for writing data thereto. The memory reading circuit is configured to issue a read command to the rewritable non-volatile memory module 106 for reading data therefrom. The memory erasing circuit is configured to issue an erase command to the rewritable non-volatile memory module 106 for erasing data therefrom. The data processing circuit is configured to process data to be written to the rewritable non-volatile memory module 106 or data read from the rewritable non-volatile memory module 106.

The host interface 204 is coupled to the memory management circuit 202 and configured to receive and identify commands and data transmitted by the host system 1000. Namely, the commands and data from the host system 1000 are transmitted to the memory management circuit 202 through the host interface 204. In the present exemplary embodiment, the host interface unit 204 complies with the USB standard. However, it should be understood that the invention is not limited thereto, and the host interface 204 may comply with the PATA standard, the IEEE 1394 standard, the PCI express standard, the SD standard, the SATA standard, the UHS-I interface standard, the UHS-II interface standard, the MS standard, the MMC standard, the eMMC interface standard, the UFS interface standard, the CF standard, the IDE standard, or other suitable data transmission standards.

The memory interface 206 is coupled to the memory management circuit 202 and configured to access the rewritable non-volatile memory module 106. Namely, data to be written into the rewritable non-volatile memory module 106 may be converted by the memory interface 206 into a format acceptable to the rewritable non-volatile memory module 106.

In an exemplary embodiment of the invention, the memory controller 104 further includes a buffer memory 252, a power management circuit 254, and an error checking and correcting (ECC) circuit 256.

The buffer memory 252 is coupled to the memory management circuit 202 and configured to temporarily store data and commands received from the host system 1000 or data received from the rewritable non-volatile memory module 106.

The power management circuit 254 is coupled to the memory management circuit 202 and configured to control the power of the memory storage apparatus 100.

The ECC circuit 256 is coupled to the memory management circuit 202 and configured to perform an ECC procedure to ensure data accuracy. In the present exemplary embodiment, when the memory management circuit 202 receives a write command from the host system 1000, the ECC circuit 256 generates an ECC code for data corresponding to the write command, and the memory management circuit 202 writes the data corresponding to the write command and the corresponding ECC code into the rewritable non-volatile memory module 106. Thereafter, when reading the data from the rewritable non-volatile memory module 106, the memory management circuit 202 simultaneously reads the corresponding ECC code, and the ECC circuit 256 executes the ECC procedure on the read data according to the corresponding ECC code. In particular, the ECC circuit 256 is configured to be capable of correcting a certain number of error bits (which is referred to as the maximum number of correctable error bits hereinafter). For instance, the maximum number of correctable error bits is 24. If the number of the error bits in the read data is equal to or less than 24, the ECC circuit 256 corrects the error bits back to the correct and accurate values according to the ECC code. Otherwise, the ECC circuit 256 reports a failure of error correcting, and the memory management circuit 202 transmits a message indicating data loss to the host system 1000.

As described above, when it is intended to read data from the memory cell, the memory controller 104 (or the memory management circuit 202) gives an instruction to the control circuit of the rewritable non-volatile memory module 106 to apply a bias for reading data to a word line (“target word line” hereinafter) connected to a to-be-read memory cell (“target memory cell” hereinafter), so as to verify the storage state of the channel of the memory cell. Besides, the memory controller 104 (or the memory management circuit 202) gives an instruction to the control circuit of the rewritable non-volatile memory module 106 to apply a bias for selecting bit lines to a bit line (“target bit line” hereinafter) connected to the target memory cell and gives an instruction to the control circuit to apply biases to bit lines that are not connected to the target memory cell, such that the channels of other memory cells that are connected to the target memory cell are conducted. To be specific, in the present exemplary embodiment, the memory controller 104 (or the memory management circuit 202) gives an instruction to the control circuit of the rewritable non-volatile memory module 106 to apply different biases to the word lines at different locations, so as to minimize the parasitic capacitance effects on the target memory cell and enhance gate controllability of the target memory cell.

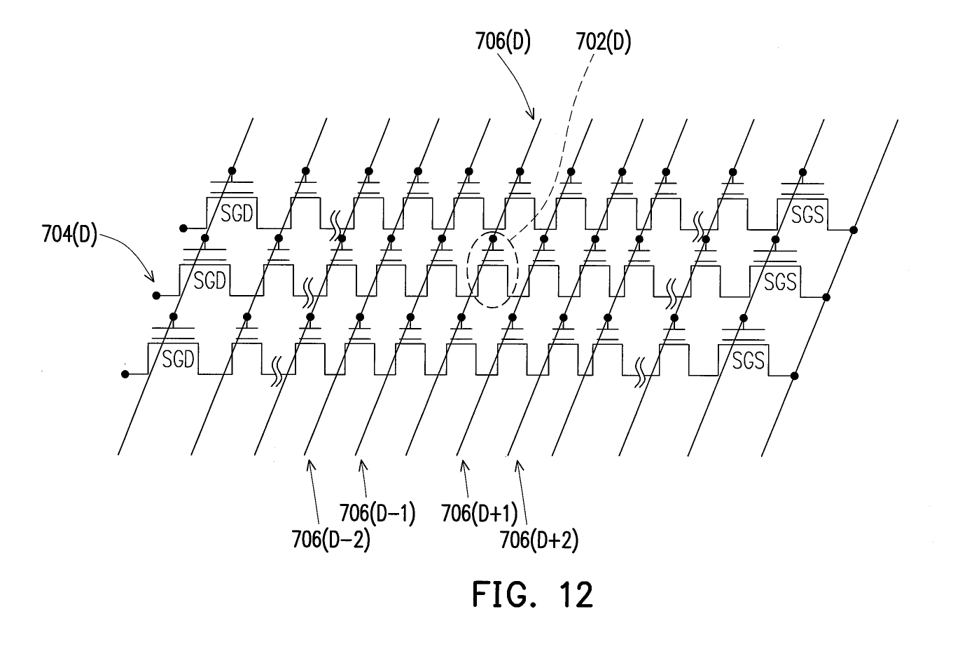

FIG. 12 is schematic diagram of applying biases to a word line and a bit line for reading data from a memory cell according to an exemplary embodiment of the present invention.

With reference to FIG. 12, when it is intended to read data from the target memory cell 702(D), the memory controller 104 (or the memory management circuit 202) gives an instruction to the control circuit of the rewritable non-volatile memory module 106 to apply a bias for reading data to the target word line 706(D) connected to the target memory cell 702(D) and apply a bias for selecting bit lines to the target bit line 704(D) connected to the target memory cell 702(D). At the same time, the memory controller 104 (or the memory management circuit 202) gives an instruction to the control circuit of the rewritable non-volatile memory module 106 to apply a relatively low bias (“the first bias” hereinafter) to the word lines 706(D+1) and 706(D−1) that are adjacent to the target word line 706(D), apply a normal bias (“the third bias” hereinafter) to the word lines 706(D+2) and 706(D−2) that are adjacent to the word lines 706(D+1) and 706(D−1), and apply a relatively high bias (“the second bias” hereinafter) to the other word lines. In the present exemplary embodiment, the first bias is lower than the second bias, and the second bias is lower than the third bias.

Particularly, when the bias for reading data is applied to the target word line that is connected to the target memory cell and when a bias is applied to the word lines that are not connected to the target memory cell, the biases applied to the word lines that are adjacent to the target word line may increase the electron volume in the charge-trapping layer in the gate of the target memory cell, such that the gate controllability of the target memory cell is reduced, and data read errors may occur. In the present exemplary embodiment, the relatively low bias, i.e., the first bias, is applied to the word lines adjacent to the target word line, so as to prevent the data read errors that are caused by the charge coupling effects between the target memory cell and the memory cells connected to the word lines adjacent to the target word line. Besides, the relatively high bias, i.e., the third bias, is applied to the word lines (e.g., the word lines 706(D+2) and 706(D−2) shown in FIG. 12) adjacent to the word lines to which the relatively low bias is applied, so as to conducted the channel of the memory cell connected to the target bit line and the word lines to which the relatively low bias is applied. Thereby, the data reading operation is completed. In an exemplary rewritable non-volatile memory module on the 10 nm scale, the first threshold bias may be set as 3.5 volts, the second threshold bias may be set as 6 volts, and the third threshold bias may be set as 7.5 volts. In an exemplary rewritable non-volatile memory module on the 13 nm scale, the first threshold bias may be set as 4.5 volts, the second threshold bias may be set as 6 volts, and the third threshold bias may be set as 8.5 volts.

According to the present exemplary embodiment, in the data reading operation, the memory controller 104 (or the memory management circuit 202) gives an instruction to the control circuit of the rewritable non-volatile memory module 106 to apply the second bias to the word lines connected to the SGS transistors. Nonetheless, according to another exemplary embodiment, in the data reading operation, the memory controller 104 (or the memory management circuit 202) gives an instruction to the control circuit of the rewritable non-volatile memory module 106 to apply a fourth bias, which is lower than the second bias, to the word lines connected to the SGS transistors, and the fourth bias.

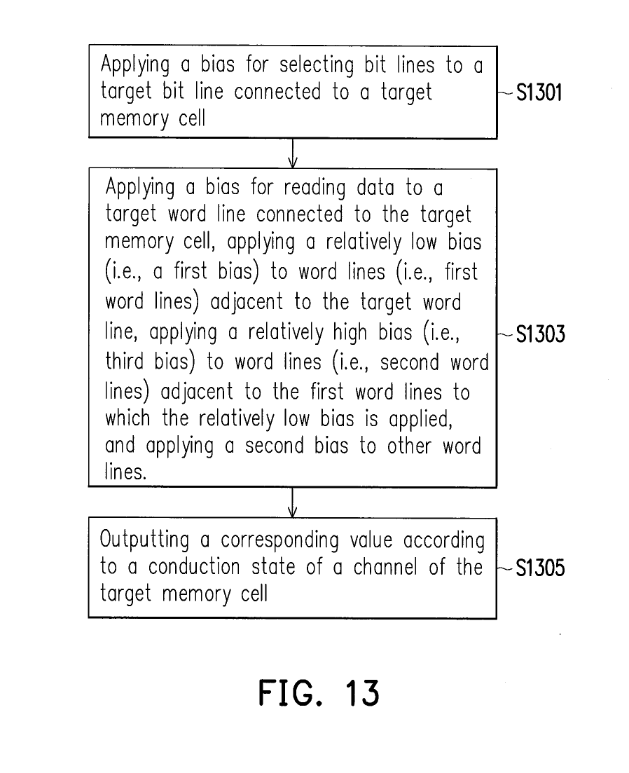

FIG. 13 is a flowchart illustrating a data reading method according to an exemplary embodiment of the present invention.

With reference to FIG. 13, when it is intended to read data from the target memory cell, in step S1301, the memory controller 104 (or the memory management circuit 202) gives an instruction to apply the bias for selecting bit lines to the target bit line connected to the target memory cell. That is, the bias (higher than 0) for selecting bit lines is applied to the target bit line connected to the target memory cell, and no bias is applied to other bit lines that are not connected to the target memory cell.

In step S1303, the memory controller 104 (or the memory management circuit 202) gives an instruction to apply the bias for reading data to the target word line connected to the target memory cell, apply the relatively low bias (i.e., the first bias) to the word lines (i.e., the first word lines) adjacent to the target word line, apply the relatively high bias (i.e., the third bias) to the word lines (i.e., the second word lines) adjacent to the first word lines to which the relatively low bias is applied, and apply the second bias to other word lines. For instance, when the rewritable non-volatile memory module 106 is an MLC NAND flash memory module, the memory controller 104 (or the memory management circuit 202) sets the bias for reading the data as the first threshold bias, the second threshold bias, or the third threshold bias described above according to the location of the data bits to be read.

In step S1305, the memory controller 104 (or the memory management circuit 202) outputs a corresponding value according to the conduction state of the channel of the target memory cell. The steps of recognizing the state of the gate voltage of the memory cell according to the conduction state of the channel of the target memory cell and thereby outputting the corresponding value are already elaborated above with reference to FIG. 9, and therefore no further description is provided hereinafter.

To sum up, the data reading method, the memory controller, and the memory storage apparatus described in the exemplary embodiments of the invention are capable of effectively minimizing the parasitic capacitance effects on the channel of the to-be-read memory cell, so as to improve the gate controllability and prevent the data read errors.

It should be noted that in the present exemplary embodiment, the memory management circuit 202 is implemented within the memory controller 104, but the present invention is not limited thereto. For example, in another exemplary embodiment, the memory management circuit 202 may be implemented within the rewritable non-volatile memory module 106, such as to be the control circuit 2212, and be coupled to the memory cell array 2220 of the rewritable non-volatile memory module 106 via an interface.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A data reading method for a rewritable non-volatile memory module, wherein the rewritable non-volatile memory module has a plurality of memory cells, a plurality of word lines, and a plurality of bit lines, and each of the memory cells is electrically connected to one of the word lines and one of the bit lines, the data reading method comprising:
applying a bias for reading data to a target word line, wherein the target word line is one of the word lines electrically connected to a target memory cell among the memory cells;
applying a bias for selecting the bit lines to a target bit line, wherein the target bit line is one of the bit lines electrically connected to the target memory cell;
applying a first bias to at least one first word line among the word lines, wherein the at least one first word line is adjacent to the target word line;
applying a second bias to the other word lines; and
outputting a corresponding value according to a conduction state of a channel of the target memory cell,
wherein the first bias is lower than the second bias.

2. The data reading method as recited in claim 1, further comprising:
applying a third bias to at least one second word line among the word lines, wherein the at least one second word line is adjacent to the at least one first word line, and
the third bias is higher than the second bias.

3. The data reading method as recited in claim 1, further comprising:
applying a fourth bias to the word lines connected to a plurality of select gate source transistors of the rewritable non-volatile memory module, wherein the fourth bias is lower than the second bias.

4. The data reading method as recited in claim 2, wherein the rewritable non-volatile memory module is a multi-level cell NAND flash memory module, the bias for reading the data is set as a first threshold bias, a second threshold bias, or a third threshold bias, the first threshold bias is lower than the second threshold bias, and the second threshold bias is lower than the third threshold bias,
wherein the step of outputting the corresponding value according to the conduction state of the channel of the target memory cell comprises:
recognizing a least significant bit of the target memory cell as being in a first state when the channel of the target memory cell is not conducted because the bias for reading the data is set as the second threshold bias;
recognizing the least significant bit of the target memory cell as being in a second state when the channel of the target memory cell is conducted because the bias for reading the data is set as the second threshold bias;
recognizing a most significant bit of the target memory cell as being in the second state when the channel of the target memory cell is not conducted because the bias for reading the data is set as the first threshold bias and the channel of the target memory cell is not conducted because the bias for reading the data is set as the third threshold bias;
recognizing the most significant bit of the target memory cell as being in the first state when the channel of the target memory cell is not conducted because the bias for reading the data is set as the first threshold bias and the channel of the target memory cell is conducted because the bias for reading the data is set as the third threshold bias; and
recognizing the most significant bit of the target memory cell as being in the second state when the channel of the target memory cell is conducted because the bias for reading the data is set as the first threshold bias and the channel of the target memory cell is conducted because the bias for reading the data is set as the third threshold bias.

5. The data reading method as recited in claim 2, wherein the rewritable non-volatile memory module is a trinary-level cell NAND flash memory module,
wherein the bias for reading the data is set as a first threshold bias, a third threshold bias, a fifth threshold bias, and a seventh threshold bias to verify a storage state of a most significant bit of the target memory cell,
wherein the bias for reading the data is set as a second threshold bias and a sixth threshold bias to verify a storage state of a center significant bit of the target memory cell,
wherein the bias for reading the data is set as a fourth threshold bias to verify a storage state of a least significant bit of the target memory cell,
wherein the first threshold bias is lower than the second threshold bias, the second threshold bias is lower than the third threshold bias, the third threshold bias is lower than the fourth threshold bias, the fourth threshold bias is lower than the fifth threshold bias, the fifth threshold bias is lower than the sixth threshold bias, and the sixth threshold bias is lower than the seventh threshold bias.

6. The data reading method as recited in claim 2, wherein the second bias is 6 volts, the first bias is 3.5 volts, and the third bias is 7.5 volts.

7. The data reading method as recited in claim 2, wherein the second bias is 6 volts, the first bias is 4.5 volts, and the third bias is 8.5 volts.

8. A circuit for reading data, the circuit comprising:
an interface configured to couple to a plurality of memory cells, a plurality of word lines, and a plurality of bit lines, wherein each of the memory cells is electrically connected to one of the word lines and one of the bit lines; and a memory management circuit coupled to the interface,
wherein the memory management circuit is configured to apply a bias for reading data to a target word line, and the target word line is one of the word lines electrically connected to a target memory cell among the memory cells,
wherein the memory management circuit is further configured to apply a bias for selecting the bit lines to a target bit line, and the target bit line is one of the bit lines electrically connected to the target memory cell,
wherein the memory management circuit is further configured to give an instruction to apply a first bias to at least one first word line among the word lines, and the at least one first word line is adjacent to the target word line,
wherein the memory management circuit is further configured to give an instruction to apply a second bias to the other word lines,
wherein the memory management circuit is further configured to output a corresponding value according to a conduction state of a channel of the target memory cell, and
the first bias is lower than the second bias.

9. The circuit as recited in claim 8, wherein the memory management circuit is further configured to give an instruction to apply a third bias to at least one second word line among the word lines, the at least one second word line is adjacent to the at least one first word line, and
the third bias is higher than the second bias.

10. The circuit as recited in claim 8, wherein the memory management circuit is further configured to give an instruction to apply a fourth bias to the word lines connected to a plurality of select gate source transistors of the rewritable non-volatile memory module, and the fourth bias is lower than the second bias.

11. The circuit as recited in claim 9, wherein the rewritable non-volatile memory module is a multi-level cell NAND flash memory module,
wherein the memory management circuit sets the bias for reading the data as a first threshold bias, a second threshold bias, or a third threshold bias, the first threshold bias is lower than the second threshold bias, and the second threshold bias is lower than the third threshold bias,
wherein in an operation of outputting the corresponding value according to the conduction state of the channel of the target memory cell, when the channel of the target memory cell is not conducted because the bias for reading the data is set as the second threshold bias, the memory management circuit indicates a least significant bit of the target memory cell as being in a first state,
wherein in the operation of outputting the corresponding value according to the conduction state of the channel of the target memory cell, when the channel of the target memory cell is conducted because the bias for reading the data is set as the second threshold bias, the memory management circuit indicates the least significant bit of the target memory cell as being in a second state,
wherein in the operation of outputting the corresponding value according to the conduction state of the channel of the target memory cell, when the channel of the target memory cell is not conducted because the bias for reading the data is set as the first threshold bias and the channel of the target memory cell is not conducted because the bias for reading the data is set as the third threshold bias, the memory management circuit indicates a most significant bit of the target memory cell as being in the second state,
wherein in the operation of outputting the corresponding value according to the conduction state of the channel of the target memory cell, when the channel of the target memory cell is not conducted because the bias for reading the data is set as the first threshold bias and the channel of the target memory cell is conducted because the bias for reading the data is set as the third threshold bias, the memory management circuit indicates the most significant bit of the target memory cell as being in the first state,
wherein in the operation of outputting the corresponding value according to the conduction state of the channel of the target memory cell, when the channel of the target memory cell is conducted because the bias for reading the data is set as the first threshold bias and the channel of the target memory cell is conducted because the bias for reading the data is set as the third threshold bias, the memory management circuit indicates the most significant bit of the target memory cell as being in the second state.

12. The circuit as recited in claim 9, wherein the rewritable non-volatile memory module is a trinary-level cell NAND flash memory module,
wherein the memory management circuit sets the bias for reading the data as a first threshold bias, a third threshold bias, a fifth threshold bias, and a seventh threshold bias to verify a storage state of a most significant bit of the target memory cell,
wherein the memory management circuit sets the bias for reading the data as a second threshold bias and a sixth threshold bias to verify a storage state of a center significant bit of the target memory cell,
wherein the memory management circuit sets the bias for reading the data as a fourth threshold bias to verify a storage state of a least significant bit of the target memory cell,
wherein the first threshold bias is lower than the second threshold bias, the second threshold bias is lower than the third threshold bias, the third threshold bias is lower than the fourth threshold bias, the fourth threshold bias is lower than the fifth threshold bias, the fifth threshold bias is lower than the sixth threshold bias, and the sixth threshold bias is lower than the seventh threshold bias.

13. The circuit as recited in claim 9, wherein the second bias is 6 volts, the first bias is 3.5 volts, and the third bias is 7.5 volts.

14. The circuit as recited in claim 9, wherein the second bias is 6 volts, the first bias is 4.5 volts, and the third bias is 8.5 volts.

15. A memory storage apparatus comprising:
a connector configured to couple to a host system;
a rewritable non-volatile memory module having a plurality of memory cells, a plurality of word lines, and a plurality of bit lines, each of the memory cells being electrically connected to one of the word lines and one of the bit lines; and
a memory controller coupled to the connector and the rewritable non-volatile memory module,
wherein the memory controller is configured to give an instruction to apply a bias for reading data to a target word line, and the target word line is one of the word lines electrically connected to a target memory cell among the memory cells,
wherein the memory controller is further configured to give an instruction to apply a bias for selecting the bit lines to a target bit line, and the target bit line is one of the bit lines electrically connected to the target memory cell,
wherein the memory controller is further configured to give an instruction to apply a first bias to at least one first word line among the word lines, and the at least one first word line is adjacent to the target word line,
wherein the memory controller is further configured to give an instruction to apply a second bias to the other word lines,
wherein the memory controller is further configured to output a corresponding value according to a conduction state of a channel of the target memory cell, and the first bias is lower than the second bias.

16. The memory storage apparatus as recited in claim 15, wherein the memory controller is further configured to give an instruction to apply a third bias to at least one second word line among the word lines, the at least one second word line is adjacent to the at least one first word line, and
the third bias is higher than the second bias.

17. The memory storage apparatus as recited in claim 15, wherein the memory controller is further configured to give an instruction to apply a fourth bias to the word lines connected to a plurality of select gate source transistors of the rewritable non-volatile memory module, and the fourth bias is lower than the second bias.

18. The memory storage apparatus as recited in claim 16, wherein the rewritable non-volatile memory module is a multi-level cell NAND flash memory module, the bias for reading the data is set as a first threshold bias, a second threshold bias, or a third threshold bias, the first threshold bias is lower than the second threshold bias, and the second threshold bias is lower than the third threshold bias,
wherein in an operation of outputting the corresponding value according to the conduction state of the channel of the target memory cell, when the channel of the target memory cell is not conducted because the bias for reading the data is set as the second threshold bias, the memory controller indicates a least significant bit of the target memory cell as being in a first state,
wherein in the operation of outputting the corresponding value according to the conduction state of the channel of the target memory cell, when the channel of the target memory cell is conducted because the bias for reading the data is set as the second threshold bias, the memory controller indicates the least significant bit of the target memory cell as being in a second state,
wherein in the operation of outputting the corresponding value according to the conduction state of the channel of the target memory cell, when the channel of the target memory cell is not conducted because the bias for reading the data is set as the first threshold bias and the channel of the target memory cell is not conducted because the bias for reading the data is set as the third threshold bias, the memory controller indicates a most significant bit of the target memory cell as being in the second state,
wherein in the operation of outputting the corresponding value according to the conduction state of the channel of the target memory cell, when the channel of the target memory cell is not conducted because the bias for reading the data is set as the first threshold bias and the channel of the target memory cell is conducted because the bias for reading the data is set as the third threshold bias, the memory controller indicates the most significant bit of the target memory cell as being in the first state,
wherein in the operation of outputting the corresponding value according to the conduction state of the channel of the target memory cell, when the channel of the target memory cell is conducted because the bias for reading the data is set as the first threshold bias and the channel of the target memory cell is conducted because the bias for reading the data is set as the third threshold bias, the memory controller indicates the most significant bit of the target memory cell as being in the second state.

19. The memory storage apparatus as recited in claim 16, wherein the rewritable non-volatile memory module is a trinary-level cell NAND flash memory module,
wherein the memory controller sets the bias for reading the data as a first threshold bias, a third threshold bias, a fifth threshold bias, and a seventh threshold bias to verify a storage state of a most significant bit of the target memory cell,
wherein the memory controller sets the bias for reading the data as a second threshold bias and a sixth threshold bias to verify a storage state of a center significant bit of the target memory cell,
wherein the memory controller sets the bias for reading the data as a fourth threshold bias to verify a storage state of a least significant bit of the target memory cell,
wherein the first threshold bias is lower than the second threshold bias, the second threshold bias is lower than the third threshold bias, the third threshold bias is lower than the fourth threshold bias, the fourth threshold bias is lower than the fifth threshold bias, the fifth threshold bias is lower than the sixth threshold bias, and the sixth threshold bias is lower than the seventh threshold bias.

20. The memory storage apparatus as recited in claim 16, wherein the second bias is 6 volts, the first bias is 3.5 volts, and the third bias is 7.5 volts.

21. The memory storage apparatus as recited in claim 16, wherein the second bias is 6 volts, the first bias is 4.5 volts, and the third bias is 8.5 volts.

22. A rewritable non-volatile memory module, comprising:
a plurality of memory cells;
a plurality of word lines, electrically connected to at least one of the of the memory cells;
a plurality of bit lines, electrically connected to at least one of the of the memory cells; and
a control circuit, electrically connected to the plurality of memory cells, the plurality of word lines, and the plurality of bit lines,
wherein the control circuit is configured to apply a bias for reading data to a target word line, and the target word line is one of the word lines electrically connected to a target memory cell among the memory cells,
wherein the control circuit is further configured to apply a bias for selecting the bit lines to a target bit line, and the target bit line is one of the bit lines electrically connected to the target memory cell,
wherein the control circuit is further configured to give an instruction to apply a first bias to at least one first word line among the word lines, and the at least one first word line is adjacent to the target word line,
wherein the control circuit is further configured to give an instruction to apply a second bias to the other word lines,
wherein the control circuit is further configured to output a corresponding value according to a conduction state of a channel of the target memory cell, and
the first bias is lower than the second bias.
